(19) United States
(12) Patent Application Publication
(10) Pub. No.: US 2010/0054368 A1
(43) Pub. Date: Mar. 4, 2010

(54) METHOD AND SYSTEM TO DETECT PACKETS OF DIFFERENT FORMATS IN A WIRELESS RECEIVER

(75) Inventor: Shuling (Julia) Feng, San Jose, CA (US)

Correspondence Address: SAWYER LAW GROUP PC, 2465 E. Bayshore Road, Suite No. 406, PALO ALTO, CA, 94303, US

(73) Assignee: RALINK TECHNOLOGY CORPORATION, Cupertino, CA (US)

(21) Appl. No.: 12/198,766

(22) Filed: Aug. 26, 2008

(51) Int. Cl. H03D 1/00

(52) U.S. Cl. 375/340

(57) ABSTRACT

A method and system for detecting packets of different formats in a receiver is disclosed. The method and system include initializing the receiver to be in a legacy mode; and receiving at least one data symbol by the receiver. The method and system include detecting if there is a high throughput (HT) signal field within a data packet and determining the format of the data packet based upon the detection of a HT signal field.

### FIELD OF THE INVENTION

The present invention relates generally to communication systems and more particularly to wireless communication systems.

### BACKGROUND OF THE INVENTION

In a wireless communication system such as a WiFi system, information is transmitted and received in orthogonal frequency-division multiplexing (OFDM) packets. A receiver in such a system needs to detect a packet and its format first, and then the receiver configures its hardware and software to receive and decode the data portion of the packet.

Each OFDM packet includes a plurality of pre-amble fields to assist the receiver in detecting, synchronizing, and conditioning the packet. The pre-amble fields are followed by an encoded signal field that carries information about data rate, packet length, and etc. The signal field is decoded and then used to configure the receiver to receive and decode the data portion of the packet. In the high throughput (HT) WiFi standard ieee draft document (802.11n), mixed mode and green field OFDM frame formats are allowed to co-exist with a low throughput legacy frame format. In this standard the mixed mode frame format allows a legacy device to handle a HT packet properly and the green field frame format allows for less overhead and therefore higher throughput in an HT only system.

Accordingly, what is desired is a system and method which allows a receiver to receive and decode data packets in an efficient fashion when the receiver can receive packets in different types of formats. The system and method should be easily implemented, cost effective and adaptable to existing communications systems. The present invention addresses such a need.

### SUMMARY OF THE INVENTION

A method and system for detecting IEEE802.11n packets of different formats in a receiver is disclosed. The method and system include initializing the receiver to be in a legacy mode; and receiving at least one data symbol by the receiver. The method and system include detecting if there is a high throughput (HT) signal field within the data packet and determining the format of the data packet based upon the detection of a HT signal field.

### BRIEF DESCRIPTION OF DRAWINGS

FIG. 1 is a block diagram which illustrates frames in the legacy format, the mixed mode format and the green field format in IEEE802.11n, respectively.

FIG. 2 shows a simplified communication system in accordance with an embodiment.

FIG. 3 illustrates the constellation diagram for L-SIG (BPSK) and the constellation diagram for HT-SIG (90-degree rotated BPSK).

### DETAILED DESCRIPTION OF PREFERRED EMBODIMENTS

The present invention relates generally to communication systems and more particularly to wireless communication systems. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

A system and method in accordance with the present invention allows for a receiver to effectively detect and decode the format of a plurality of packets transmitted in a wireless network. Specifically, the system allows for a receiver which can receive packets in different formats to detect whether the IEEE802.11n packets are in a high throughput (HT) format or a legacy OFDM format. In so doing, a receiver can operate efficiently when receiving and decoding packets.

Although an embodiment will be described based upon a WiFi system in which orthogonal frequency-division multiplexing (OFPM) packets are utilized. One of ordinary skill in the art recognizes a system and method in accordance with an embodiment can be utilized in a variety of embodiments and that use would be within the spirit and scope of the present invention. For example, the receiver could receive, for example, CCK packets, Ethernet packets and the like and their use would be within the spirit and scope of the present invention. For example, the types of high throughput formats may differ from mixed mode format and the green format disclosed herein but those formats would still be applicable in a system and method in accordance with the present invention. Accordingly, although the system and method in accordance with the present invention will be discussed in the context of a particular embodiment, one of ordinary skill in the art recognizes that it can be utilized in a variety of environments and is not limited to the embodiments described herein.

In a system and method in accordance with an embodiment, the detection of high throughput frame formats in a WiFi system (e.e., structured 802.11n) is based on the detection of high throughout signal field (HT-SIG) field, which is modulated in a 90 degree rotated BPSK. A method and system in accordance within an embodiment detects the HT-SIG field by comparing the equalized symbols' of the power in I and Q parts the packets. In an embodiment, the detector distinguishes whether the packets received OFDM frames are in the mixed mode, green field, and legacy formats. The detector in accordance with an embodiment can distinguish frames among mixed mode, green field, and legacy formats without parallel decoding. A system and method in accordance with an embodiment provides a fast, reliable, efficient, and well-fitted implementation in a plurality of receiver designs.

A system that utilizes a detection procedure in accordance with the present invention can take the form of an entirely hardware implementation, an entirely software implementation; or an implementation containing both hardware and software elements. In one implementation, this detection procedure is implemented in software, which includes, but is not limited to, application software, firmware, resident software, microcode, etc.

Furthermore, the detection procedure can take the form of a computer program product accessible from a computer-usable or computer-readable medium providing program code for use by or in connection with a computer or any instruction execution system. For the purposes of this description, a computer-usable or computer-readable medium can be any apparatus that can contain, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk, and an optical disk. Current examples of optical disks include DVD, compact disk-read-only memory (CD-ROM), and compact disk-read/write (CD-R/W). To describe the features of the present invention in more detail, refer now to the following description in conjunction with the accompanying Figures.

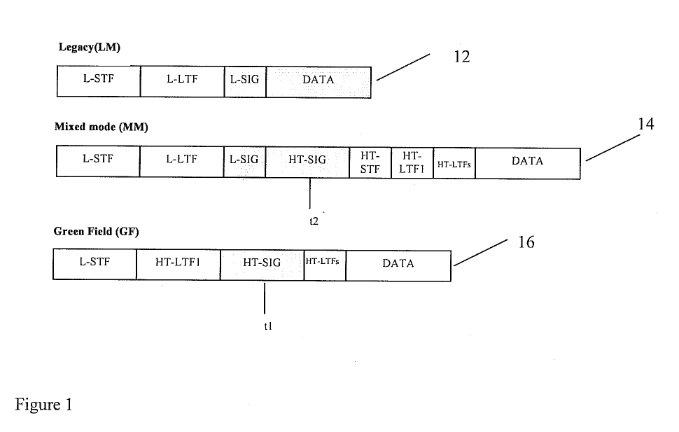

FIG. 1 is a block diagram which illustrates frames in the legacy format 12, the mixed mode format 14 and the green field format 16, respectively. A receiver in accordance with the 802.11n format needs to distinguish between the legacy, mixed mode, and green field frame formats to further process the packet. In other words, the receiver needs to be able to distinguish a HT-SIG field from a L-SIG field and data symbols. The L-SIG field is BPSK modulated, i.e., the constellation only has I power. Data symbols can be BPSK, QPSK, and QAM modulated. This means the constellation either has I power only or have equal I power and Q power. According to the 802.11n specification, the HT-SIG field has a BPSK modulation and then the constellation is 90-degree rotated. So accordingly, the HT-SIG field only has Q signals part of constellation power. Accordingly, since the HT-SIG field only has the Q signals of the constellation power, this feature can be used to differentiate it from a normal BPSK modulation of the L-Sig field.

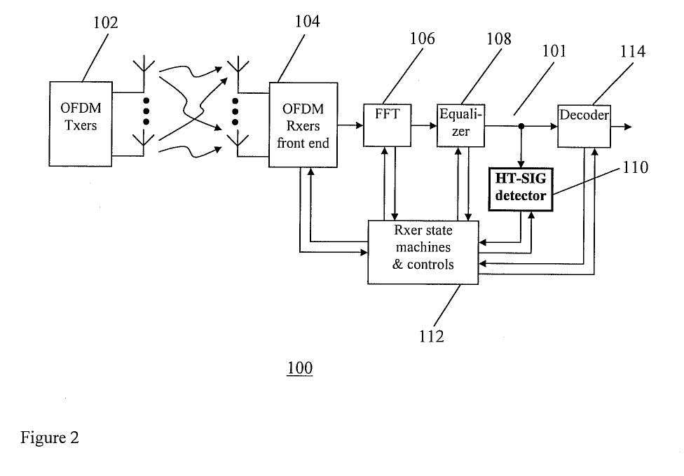

FIG. 2 shows a simplified communication system 100 in accordance with an embodiment. The system 100 includes an OFDM transmitter 102 which provides data packet to a receiver 101. The receiver 101 comprises a plurality of OFDM receivers 104 which receive the data packets and provide the data to a Fast Fourier transform (FFT) module 106 and a receiver state machine and controls module 112. The FFT module 106 provides the data to an equalizer 108 and also communicates with receiver state and control module 112.

The equalizer 108 provides the equalized data packets to a decoder 114 and a high throughput signal (HT) detector module 110. The equalizer module 108 also communicates with module 112. The HT detector module 110 communicates with the receiver state and controls modules 112. The decoder 114 also communicates with the module receiver state and controls 112. The received signals are conditioned in the front end of OFDM receiver 104. Each time domain symbol is transformed to frequency domain sub-carriers by FFT 106, and then equalized by equalizer 108. The HT-SIG detection is based on equalized symbols provided by the equalizer 108. The HT-SIG detection module 110 is controlled in receiver state machines 112.

The detection of high throughoutput formats in 802.11n is based on the detection of the HT-SIG field, which is modulated in 90 degree rotated BPSK. A simple and efficient method described here to detect the HT-SIG field is to compare the equalized symbols' power in I and Q parts.

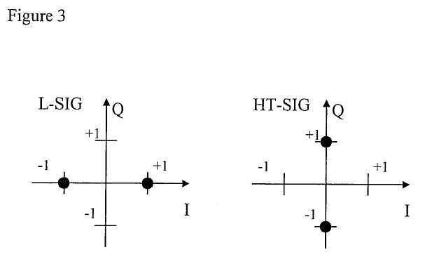

FIG. 3 illustrates the constellation diagram for L-SIG (BPSK) and the constellation diagram for HT-SIG (90-degree rotated BPSK). The 90-degree rotated BPSK detection can be performed by comparing equalized signal energy on I axis and Q axis. The detection accuracy depends on the equalized signal constellation quality. HT-SIG field is detected once a 90-degree rotated BPSK is detected. Thus high throughput modes are detected.

In a system and method in accordance with the embodiment, the receiver state machine is initialized in legacy mode. If the HT-SIG field is detected at time t1 (shown in FIG. 1), a green field frame is received. If green field frame is not detected, it is determined if the decoded data rate from the L-SIG frame is at a predetermined rate (i.e. 6 Mbps), and if the HT-SIG field is detected at time t2. If both of these conditions are satisfied, then a mixed mode frame is received. If these conditions are not met, the receiver remains in legacy mode.

As before mentioned, the receiver is in legacy mode before the HT-SIG field is detected. Therefore, the receiver needs to buffer HT-SIG fields while decoding L-SIG files, or to parallel decode L-SIG and the HT-SIG symbols. In an embodiment, in order to reduce buffering and eliminate parallel decoding, the HT-SIG detection is based only on the first HT-SIG symbol. This HT-SIG detection module 110 is used to detect both mixed mode and green field packet formats. To describe the features of the operation the detection module 110 in accordance with an embodiment refer now to the following description.

### Detect HT-SIG Field by Detecting 90 Degree Rotated BPSK Modulation

In an embodiment, the HT-SIG field detection is performed on all 48 equalized data sub-carriers in the first HT-SIG symbol. Assuming the equalized data sub-carriers are represented as r[i], i=0, 1, . . . , 47. Then the power on I axis and Q axis is,

$${P}_{i} = {\sum }_{i = 0}^{47} ( r [ i ] . {i}^{*} r [ i ] . i )$$

$${P}_{q} = {\sum }_{i = 0}^{47} ( r [ i ] . {q}^{*} r [ i ] . q )$$

For example, note that the number of data symbols in HT-SIG in a 40 MHz receiver is 48*2. Since the upper band is a duplicated version of the lower band, and the bands are combined in equalization, the number of data sub-carriers used for HT-SIG field detection is still 48.

If a 90 degree rotated BPSK signal is received, the noise power N=2Pᵢ, and signal power S=P_{q}−Pᵢ. Therefore a HT-SIG field is detected if S>α·N; where α is the critical signal to noise (SNR). The detection criteria is equivalent to:

HT-SIG field is detected if P_{q}>(2·α+1)·Pᵢ

To determine the proper detection threshold, the term (2·α+1) will be referred to hereafter as the detection threshold, then the HT-SIG field is detected if P_{q}>threshold·Pᵢ

To determine the proper detection threshold the HT-SIG field detection is tested in various frames. To ensure a high detection rate and a low false detection rate, a proper range of the detection threshold is 1.5-2.0. This corresponds to proper HT-SIG field detection for equalized SNR as low as −6 dB to −3 dB.

A system and method in accordance with the present invention allows for a receiver to effectively detect and decode the format of a plurality of packets transmitted in a wireless network. Specifically, the system allows for a receiver which can receive packets in different formats to detect whether the packets are in a high throughput (HT) format or a legacy OFDM format. In so doing, a receiver can operate efficiently when receiving and decoding packets.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for detecting packets of different formats in a receiver comprising:
initializing the receiver to be in a legacy mode;
receiving at least one data symbol by the receiver; and
detecting if there is a high throughput (HT) signal field within a data packet; and
determining the format of the data packet based upon the detection of a high throughput signal field.

2. The method of claim 1 wherein the different formats comprises a green field format, a mixed mode format and a legacy mode format.

3. The method of claim 1 wherein if the HT signal field is detected within a first predetermined time period, a first HT format is detected.

4. The method of claim 3 wherein if the data rate from a low throughput signal field is at a predetermined value and a HT signal field is detected within a second predetermined period after the first predetermined true period, a second HT format is detected; and wherein if neither of the above conditions are met, the receiver remains in a legacy mode.

5. The method of claim 1 wherein the HT signal field is detected once a binary phase shift keying (BPSK) modulation is appended to the packet.

6. The method of claim 1 wherein the detection compares equalizer symbols power in the I and Q signals in a constellation diagram.

7. The method of claim 1 wherein a threshold is provided based upon the signal to noise ratio (SNR) of the HT signal field to ensure that the packets are properly detected.

8. The method of claim 1 wherein a proper range of detection is based upon the S>α·N where S is the signal power, N is the noise power, and α is the signal to noise ratio.

9. The method of claim 8 wherein the detection threshold comprises (2·α+1).

10. The method of claim 9 wherein a proper range of the detection threshold is between 1.5 and 2.

11. A system for detecting packets of different formats in a receiver, comprising:
means for initializing the receiver to be in a legacy mode;
means for receiving at least one data symbol by the receiver; and
means for detecting if there is a high throughput (HT) signal field within a data packet; and
means for determining the format of the data packet based upon the detection of a high throughput signal field.

12. The system of claim 11 wherein the different formats comprises a green field format, a mixed mode format and a legacy mode format.

13. The system of claim 11 wherein if the HT signal field is detected within a first predetermined time period, a first HT format is detected.

14. The system of claim 13 wherein if that data rate from a low throughput signal field is at a predetermined value and a HT signal field is detected within a second predetermined period after the first predetermined true period, a second HT format is detected; and wherein if neither of the above conditions are met, the receiver remains in a legacy mode.

15. The system of claim 11 wherein the HT signal field is detected once a binary phase shift keying (BPSK) modulation is appended to the packet.

16. The system of claim 11 wherein the detection compares equalizer symbols power in the I and Q signals in a constellation diagram.

17. The system of claim 11 wherein a threshold is provided based upon the signal to noise ratio (SNR) of the HT signal field to ensure that the packets are properly detected.

18. The system of claim 1 wherein a proper range of detection is based upon the S>α·N where S is the signal power, N is the noise power, and α is the signal to noise ratio.

19. The system of claim 18 wherein the detection threshold comprises (2·α+1).

20. The system of claim 19 wherein a proper range of the detection threshold is between 1.5 and 2.
